(19) United States
(12) Patent Application Publication
(10) Pub. No.: US 2026/0219123 A1
(43) Pub. Date: Jul. 30, 2026

(54) ELECTRONIC DEVICE FOR DETECTING EXTERNAL PRESSURE AND ERROR OCCURRENCE AND CONTROL METHOD THEREOF

(71) Applicant: SAMSUNG ELECTRONICS CO., LTD., Suwon-si (KR)

(72) Inventors: Yoonsup KIM, Suwon-si (KR); Jinho KIM, Suwon-si (KR); Junesuk LEE, Suwon-si (KR)

(73) Assignee: SAMSUNG ELECTRONICS CO., LTD., Suwon-si (KR)

(21) Appl. No.: 19/573,368

(22) Filed: Mar. 20, 2026

Related U.S. Application Data
(63) Continuation of application No. PCT/KR2024/019406, filed on Nov. 29, 2024.

(30) Foreign Application Priority Data
Dec. 26, 2023 (KR) 10-2023-0191708

(51) Int. Cl. G01L 27/00; G01L 9/00; G01R 19/10; G01R 19/165; G01R 31/327

(52) U.S. Cl. CPC G01L 27/007; G01L 9/00; G01R 19/10; G01R 19/16566; G01R 31/3277

(57) ABSTRACT

An electronic apparatus including a transistor including a drain terminal connected to a first voltage source; a first conductor including a first end connected to a gate terminal of the transistor; a second conductor including a first end connected to a source terminal of the transistor; a first resistor including the first voltage source and a second end of the first conductor; a second resistor connecting ground and a second end of the second conductor; memory storing instructions; and at least one processor configured to execute the instructions to identify whether the first conductor and the second conductor are in contact according to external pressure. The at least one processor is configured to execute the instructions to identify whether an error occurs in the electronic apparatus based on a first voltage at the second end of the first conductor and a second voltage at the second end of the second conductor.

### CROSS-REFERENCE TO RELATED APPLICATIONS

This application is a continuation of International Application No. PCT/KR2024/019406, filed on Nov. 29, 2024, which is based on and claims priority to Korean Patent Application No. 10-2023-0191708, filed on Dec. 26, 2023, in the Korean Intellectual Property Office, the disclosure of which is incorporated by reference herein in their entireties.

### BACKGROUND

### 1. Field

The present disclosure relates to an electronic apparatus and a controlling method thereof, and more particularly, to an electronic apparatus for detecting external pressure and occurrence of an error, and a controlling method thereof.

### 2. Description of Related Art

With the development of electronic technology, electronic apparatuses providing various functions have been developed. In particular, in recent years, robots, home appliances, and mobile electronic apparatuses have been developed, and accordingly, safety has become an important consideration.

To secure safety functions of such apparatuses, a Safety PLC (Safety Controller, Safety Bumper) have been used. However, since they are expensive as they include a plurality of hardware modules and controllers. The Safety PLC may use a hardware module for each sensor or switch, making miniaturization difficult, and may use replacement of hardware modules when product specifications are changed.

### SUMMARY

According to an aspect of the disclosure, an electronic apparatus including: a transistor including a drain terminal connected to a first voltage source; a first conductor including a first end connected to a gate terminal of the transistor; a second conductor including a first end connected to a source terminal of the transistor; a first resistor connecting the first voltage source and a second end of the first conductor; a second resistor connecting ground and a second end of the second conductor; memory storing instructions; and at least one processor configured to execute the instructions to identify whether the first conductor and the second conductor are in contact according to external pressure. The at least one processor is configured to execute the instructions to identify whether an error occurs in the electronic apparatus based on a first voltage at the second end of the first conductor and a second voltage at the second end of the second conductor.

The at least one processor is configured to execute the instructions to: based on the first voltage and the second voltage being the same, identify that no error has occurred in the electronic apparatus; or based on the first voltage and the second voltage being different, identify that an error has occurred in the electronic apparatus.

The at least one processor is configured to execute the instructions to: based on the first voltage and the second voltage being below a first threshold, identify that the first conductor and the second conductor are in contact; based on the first voltage and the second voltage being greater than a second threshold, identify that the first conductor and the second conductor are not in contact; or based on the first voltage being greater than the second threshold and the second voltage being lower than the first threshold, identify that an error has occurred in the electronic apparatus.

The electronic apparatus is included in an external apparatus. The at least one processor is configured to execute the instructions to control the external apparatus based on contact information indicating that the first conductor and the second conductor are in contact or error information indicating that an error has occurred in the electronic apparatus.

The first resistor has a resistance value greater than that of the second resistor such that, based on the first conductor and the second conductor being in contact, the first voltage and the second voltage are identified being below a first threshold.

The electronic apparatus including a third resistor connecting a gate terminal of the transistor and the ground.

The electronic apparatus including a first photo coupler including a first end connected to the second end of the first conductor and a second end connected to a second voltage source; and a second photo coupler including a first end connected to the second end of the second conductor and a second end connected to the second voltage source. The at least one processor is configured to execute the instructions to identify whether an error occurs in the electronic apparatus based on the second end of the first photo coupler and the second end of the second photo coupler.

The first voltage source is capable of changing a voltage. The second voltage source is configured to provide a voltage for driving the at least one processor.

The electronic apparatus including a first Schmitt trigger circuit including a first end connected to the second end of the first photo coupler; and a second Schmitt trigger circuit including a first end connected to the second end of the second photo coupler. The at least one processor is configured to execute the instructions to identify whether an error occurs in the electronic apparatus based on the second end of the first Schmitt trigger circuit and the second end of the second Schmitt trigger circuit.

The electronic apparatus including a switch connecting the first conductor and the second conductor. The at least one processor is configured to execute the instructions to identify whether an error occurs in the switch based on the first voltage and the second voltage.

According to an aspect of the disclosure, a method of controlling an electronic apparatus, including: identifying whether a first conductor and a second conductor are in contact according to external pressure. The first conductor includes 1) a first end connected to a gate terminal of a transistor having a drain terminal connected to a first voltage source and 2) a second end connected to the first voltage source through a first resistor. The second conductor includes a first end connected to a source terminal of the transistor and a second end connected to ground through a second resistor. The method including identifying whether an error occurs in the electronic apparatus based on a first voltage at the second end of the first conductor and a second voltage at the second end of the second conductor.

The identifying whether an error occurs includes: based on the first voltage and the second voltage being the same, identifying that no error has occurred in the electronic apparatus; or based on the first voltage and the second voltage being different, identifying that an error has occurred in the electronic apparatus.

The identifying whether an error occurs includes: based on the first voltage and the second voltage being below a first threshold, identifying that the first conductor and the second conductor are in contact; based on the first voltage and the second voltage being greater than a second threshold, identifying that the first conductor and the second conductor are not in contact; or based on the first voltage being greater than the second threshold and the second voltage being lower than the first threshold, identifying that an error has occurred in the electronic apparatus.

The electronic apparatus is included in an external apparatus. The method further includes: controlling the external apparatus based on contact information indicating that the first conductor and the second conductor are in contact or error information indicating that an error has occurred in the electronic apparatus.

The first resistor has a resistance value greater than that of the second resistor such that, based on the first conductor and the second conductor being in contact, the first voltage and the second voltage are identified being below a first threshold.

### BRIEF DESCRIPTION OF THE DRAWINGS

FIGS. 1A, 1B, 1C, and 1D are views provided to explain a safety bumper to facilitate understanding of the present disclosure;

FIG. 2 is a circuit diagram illustrating configuration of an electronic apparatus according to an embodiment;

FIG. 3 is a view illustrating an operation of identifying a state of an electronic apparatus according to an embodiment;

FIG. 4 is a circuit diagram illustrating configuration of an electronic apparatus according to an embodiment;

FIGS. 5 and 6 are block diagrams provided to explain a structure and utilization of an electronic apparatus according to an embodiment; and

FIG. 7 is a flowchart provided to explain a method of controlling an electronic apparatus according to an embodiment.

### DETAILED DESCRIPTION

The present disclosure is to provide an electronic apparatus for identifying not only external pressure applied to the electronic apparatus but also whether an error occurs in the electronic apparatus and a controlling method thereof.

Various embodiments in this disclosure and the terms used herein do not intend to limit the technical features in this disclosure to specific embodiments, but should be understood to include various modifications, equivalents or alternatives of the corresponding embodiments.

With respect to the description of the drawings, similar components may be denoted by similar reference numerals.

The singular form of a noun corresponding to an item may include one item or a plurality of items, unless the relevant context clearly indicates otherwise.

In this disclosure, “A or B”, “at least one of A and B”, “at least one of A or B”, “A, B or C”, “at least one of A, B and C”, and “at least one of A, B, or C” may each include any one of the items listed together in the corresponding phrase, or any possible combination thereof.

Terms “first”, “second”, “1^{st},” or “2^{nd},” may be used simply to distinguish the corresponding component from other corresponding components, and may limit the corresponding components in other aspects (e.g.: importance or order).

When it is mentioned that one (e.g., first) component is “coupled” or “connected” to another (e.g., second) component, with or without the terms “functionally” or “communicatively”, it means that the component can be connected to another component directly (e.g. wired), wirelessly, or through a third component.

Terms such as “have” or “include” are intended to designate the presence of features, numbers, steps, operations, components, parts, or a combination thereof described in this disclosure, but are not intended to exclude the presence or addition of one or more other features, numbers, steps, operations, components, parts, or a combination thereof in advance.

When a component is said to be “connected,” “coupled,” “supported,” or “in contact” with another component, this means not only when the components are directly connected, coupled, supported, or in contact, but also when they are indirectly connected, coupled, supported, or in contact through a third component.

When a component is said to be located “on” another component, this includes not only a case where a component is in contact with another component, but also a case where another component exists between the two components.

The term “and/or” includes a combination of a plurality of related elements described herein or any element of a plurality of related elements described herein.

Hereinafter, principles of operations and embodiments of the present disclosure will be described with reference to the accompanying drawings.

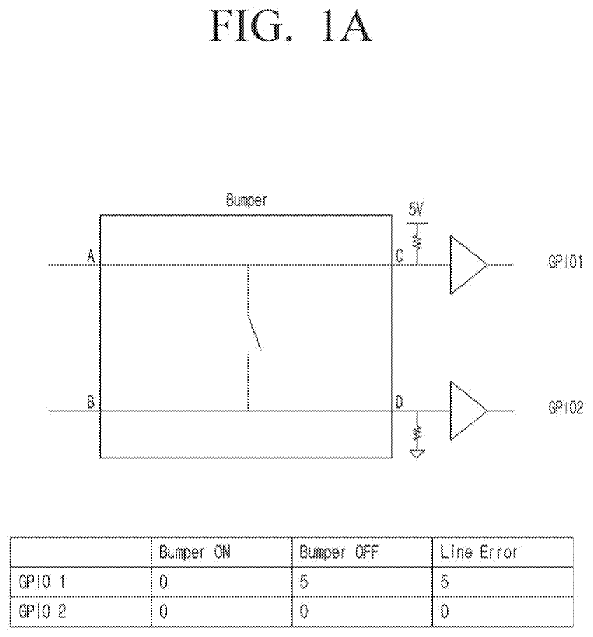

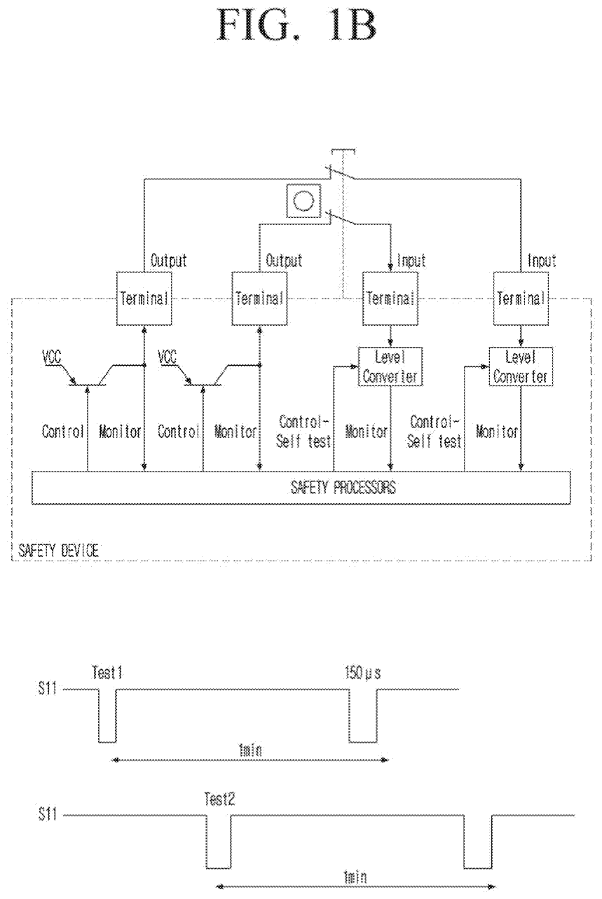

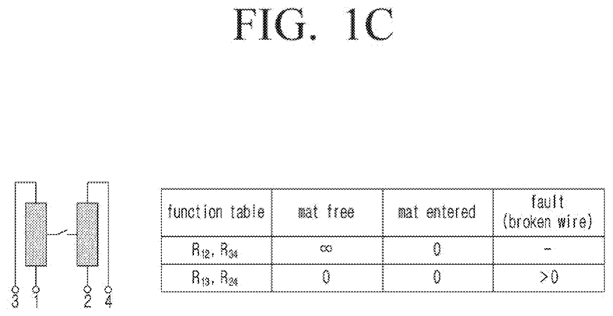

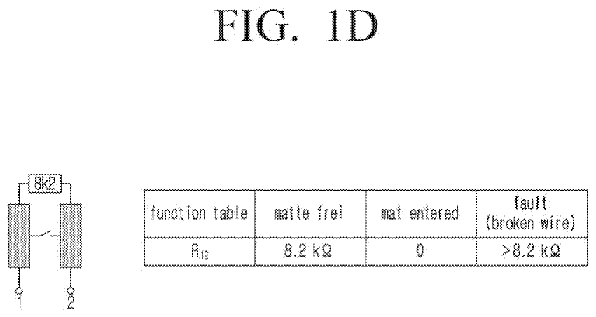

FIGS. 1A, 1B, 1C, and 1D are views provided to explain a safety bumper to facilitate understanding of the present disclosure.

A safety bumper may be an apparatus for detecting external pressure.

For example, the safety bumper may identify external pressure by detecting whether two conductors are in contact with each other. For example, when a first conductor of the safety bumper is denoted as an AC line in FIG. 1A, a second conductor of the safety bumper is denoted as a BD line in FIG. 1A, and contact between the two conductors is represented by a switch, it is possible to identify whether the two conductors are in contact with each other based on GPIO 1 and GPIO 2. When both GPIO 1 and GPIO 2 are 0, it is identified that the two conductors are in contact with each other and that external pressure is applied, and when GPIO 1 is 5 and GPIO 2 is 0, it is identified that the two conductors are not in contact with each other and that external pressure is not applied.

However, when a line error such as disconnection of the first conductor or the second conductor occurs, GPIO 1 may be 5 and GPIO 2 may be 0. In other words, referring to FIG. 1A, it may not be possible to distinguish between a case in which the two conductors are not in contact with each other and a case in which a line error occurs.

To address this issue, in FIG. 1B, an error may be identified based on a signal having a predetermined pattern output from one port of a processor and a signal received at another port. However, a timer for signal output, an interrupt for input, and the like may be needed, resulting in a complicated circuit and an increase in manufacturing cost.

Alternatively, as illustrated in FIG. 1C, whether an error occurs may be identified based on a state of a resistance value of each of the four ports of a safety bumper, or as illustrated in FIG. 1D, whether an error occurs may be identified based on states of resistance values of the two ports of the safety bumper. However, in the cases of FIGS. 1C and 1D, four channels of a differential input analog to digital converter (ADC0 may be needed. An ADC-based method may be affected by a length of the safety bumper, an applied voltage, temperature, and the like, thereby resulting in a high likelihood of erroneous determination.

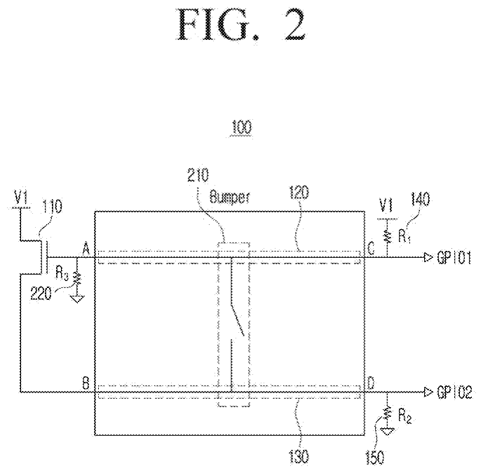

FIG. 2 is a circuit diagram illustrating configuration of an electronic apparatus 100 according to an embodiment.

In some embodiments, the electronic apparatus 100 may be an apparatus for detecting external pressure. For example, the electronic apparatus 100 may be an apparatus for detecting external pressure applied to the electronic apparatus 100 based on whether two conductors are in contact with each other, and may be referred to as a safety bumper, a safety MCU, or the like.

As illustrated in FIG. 2, the electronic apparatus 100 may include a transistor 110 including a drain terminal connected to a first voltage source V1, a first conductor 120 including one end connected to a gate terminal of the transistor 110, a second conductor 130 including one end connected to a source terminal of the transistor 110, a first resistor R1 140 connecting the first voltage source and the other end of the first conductor 120, and a second resistor R2 150 connecting ground and the other end of the second conductor 130. In FIG. 2, for convenience of description, the first conductor 120 is illustrated as an AC line, the second conductor 130 is illustrated as a BD line, and contact between the conductors is illustrated as a switch 210. Here, the first resistor 140 may have a resistance value greater than that of the second resistor 150 such that, when the first conductor 120 and the second conductor 130 are in contact with each other, a first voltage and a second voltage are identified as low values. In some embodiments, the first voltage and the second voltage may be identified as low values as a result of being less than a threshold.

A GPIO 1 pin and a GPIO 2 pin may be applied with a voltage at the other end of the first conductor 120 and a voltage at the other end of the second conductor 130, respectively. Here, a GPIO pin may be a general-purpose input/output pin, which is a digital signal pin of an integrated circuit or an electrical circuit board, the operation of which, including input or output, may be controlled by a user at runtime.

The electronic apparatus 100 may further include a third resistor R3 220 connecting the gate terminal of the transistor 110 and ground.

The electronic apparatus 100 may further include one or more processors 160 configured to identify whether the first conductor 120 and the second conductor 130 are in contact with each other according to external pressure. However, the present disclosure is not limited thereto, and the electronic apparatus 100 may be implemented without including the processor 160. In this case, the electronic apparatus 100 may be connected to an external apparatus and may provide, to a processor of the external apparatus, information about whether contact occurs and whether an error occurs through the GPIO 1 pin and the GPIO 2 pin. Hereinafter, for convenience of description, the electronic apparatus 100 will be described as including the processor 160.

The one or more processors may include one or more of a central processing unit (CPU), a graphics processing unit (GPU), an accelerated processing unit (APU), a many integrated core (MIC), a neural processing unit (NPU), a hardware accelerator, or a machine learning accelerator. The one or more processors may control one or any combination of the other components of the electronic apparatus 100, and may perform communication-related operations or data processing. The one or more processors may execute at least one program or instruction stored in the memory. For example, the one or more processors may perform a method according to an embodiment by executing at one or more instructions stored in the memory.

When a method according to an embodiment includes a plurality of operations, the plurality of operations may be performed by one processor or by a plurality of processors. For example, when a first operation, a second operation, and a third operation are performed by the method according to an embodiment, all of the first operation, the second operation, and the third operation may be performed by the first processor, or the first operation and the second operation may be performed by the first processor (e.g., a general-purpose processor) and the third operation may be performed by the second processor (e.g., an artificial intelligence-dedicated processor).

The one or more processors may be implemented as a single core processor including a single core, or as one or more multicore processors including a plurality of cores (e.g., homogeneous multicore or heterogeneous multicore). When the one or more processors are implemented as a multicore processor, each of the plurality of cores included in the multicore processor may include internal memory of the processor, such as cache memory and an on-chip memory, and a common cache shared by the plurality of cores may be included in the multicore processor. Each of the plurality of cores (or some of the plurality of cores) included in the multi-core processor may independently read and perform program instructions to implement the method according to an embodiment, or all (or some) of the plurality of cores may be coupled to read and perform program instructions to implement the method according to an embodiment.

When a method according to an embodiment includes a plurality of operations, the plurality of operations may be performed by one core of a plurality of cores included in a multi-core processor, or may be performed by a plurality of cores. For example, when a first operation, a second operation, and a third operation are performed by a method according to an embodiment, all of the first operation, the second operation, and the third operation may be performed by the first core included in the multi-core processor, or the first operation and the second operation may be performed by the first core included in the multi-core processor and the third operation may be performed by the second core included in the multi-core processor.

In the embodiments of the present disclosure, the one or more processors may mean a system-on-chip (SoC) in which one or more processors and other electronic components are integrated, a single-core processor, a multi-core processor, or a core included in a single-core processor or multi-core processor and here, the core may be implemented as CPU, GPU, APU, MIC, NPU, hardware accelerator, or machine learning accelerator, etc., but the core is not limited to the embodiments of the present disclosure. However, for convenience of description, operations of the electronic apparatus 100 will be described using the term “processor 160.”

The processor 160 may identify whether an error occurs in the electronic apparatus 100 based on a first voltage at the other end of the first conductor 120 and a second voltage at the other end of the second conductor 130.

For example, when the first voltage and the second voltage are identical, the processor 160 may identify that no error has occurred in the electronic apparatus 100, and when the first voltage and the second voltage are different, the processor 160 may identify that an error has occurred in the electronic apparatus 100.

For example, the processor 160 may identify that the first conductor 120 and the second conductor 130 are in contact with each other when the first voltage and the second voltage are low values, may identify that the first conductor 120 and the second conductor 130 are not in contact with each other when the first voltage and the second voltage are high values, and may identify that an error has occurred in the electronic apparatus 100 when the first voltage is a high value and the second voltage is a low value. In some embodiments, a voltage may be identified as a low value as a result of being less than a first threshold and a voltage may be identified as a high value as a result of being greater than a second threshold.

The electronic apparatus 100 may be included in an external apparatus, and the processor 160 may control the external apparatus based on contact information indicating that the first conductor 120 and the second conductor 130 are in contact with each other or error information indicating that an error has occurred in the electronic apparatus 100. For example, the external apparatus may be a robot, the electronic apparatus 100 may be attached to a hand of the robot, and the processor 160 may identify that the robot hand has grasped an object based on contact information and may maintain pressure applied to the robot hand without increasing the pressure.

Through the operations described above, the electronic apparatus 100 may detect contact information while also detecting whether an error has occurred through a simple circuit configuration.

In addition, since only simple components such as a transistor are added, a manufacturing cost of the electronic apparatus 100 may also be reduced.

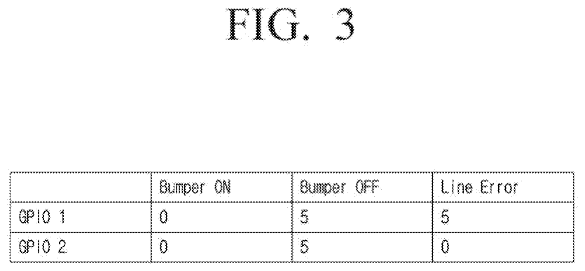

FIG. 3 is a view illustrating an operation of identifying a state of the electronic apparatus 100 according to an embodiment.

As illustrated in FIG. 3, the processor 160 may identify that the first conductor 120 and the second conductor 130 are in contact with each other when the first voltage at the other end of the first conductor 120 and the second voltage at the other end of the second conductor 130 are low values, may identify that the first conductor 120 and the second conductor 130 are not in contact with each other when the first voltage and the second voltage are high values, and may identify that an error has occurred in the electronic apparatus 100 when the first voltage is a high value and the second voltage is a low value. In FIG. 3, for convenience of description, the high value is denoted as 5 and the low value is denoted as 0; however, these values may be changed in various ways.

Hereinafter, the first voltage and the second voltage will be described with reference to the circuit of FIG. 2.

First, when no external pressure is applied, the first conductor 120 and the second conductor 130 may not be in contact with each other. In this case, the transistor 110 is turned on by a voltage of the first voltage source V1 having a high value, and a drain terminal and a source terminal of the transistor 110 are electrically connected, such that the voltage of the first voltage source V1 having the high value may also be applied to the source terminal in the same manner as the drain terminal. Accordingly, the first voltage and the second voltage have high values, and the processor 160 may identify that the first conductor 120 and the second conductor 130 are not in contact with each other.

When external pressure is applied, the first conductor 120 and the second conductor 130 may be in contact with each other. In this case, a path connecting the first voltage source V1, the first resistor 140, a contact portion, the second resistor 150 and/or the third resistor 220, and ground is formed, and a voltage at the contact portion may be determined through voltage division by the first resistor 140 and the second resistor 150 and/or the third resistor 220. Here, a resistance value of the first resistor 140 is set to be greater than that of the second resistor 150, and as the contact portion has a low value, the transistor 110 may be turned off. Accordingly, the first voltage and the second voltage have low values, and the processor 160 may identify that the first conductor 120 and the second conductor 130 are in contact with each other.

When an error occurs in the electronic apparatus 100, such as when the first conductor 120 or the second conductor 130 is disconnected, the first voltage may have a high value due to the voltage of the first voltage source V1. On the other hand, a low value is applied to the gate of the transistor 110, and as the transistor 110 is turned off, the second voltage may have a low value. Since the first voltage is a high value and the second voltage is a low value, the processor 160 may identify that an error has occurred in the electronic apparatus 100.

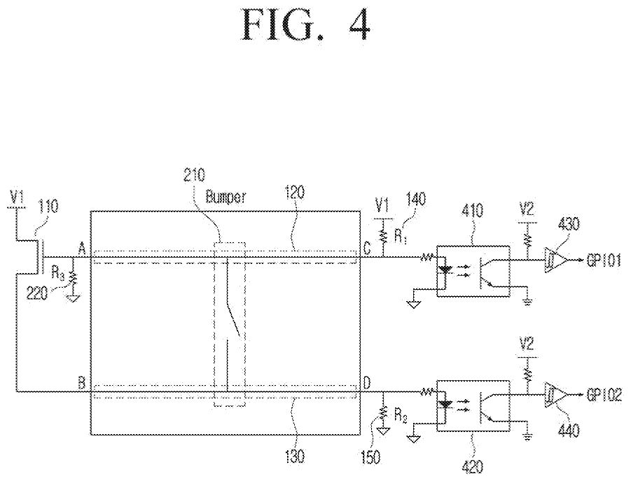

FIG. 4 is a circuit diagram illustrating configuration of the electronic apparatus 100 according to an embodiment.

The electronic apparatus 100 may further include a first photocoupler 410 including one end connected to the other end of the first conductor 120 and the other end connected to the second voltage source V2, and a second photocoupler 420 including one end connected to the other end of the second conductor 130 and the other end connected to the second voltage source V2, and the processor 160 may identify whether an error occurs in the electronic apparatus 100 based on the other end of the first photocoupler 410 and the other end of the second photocoupler 420. In addition, the electronic apparatus 100 may further include a resistor formed between the other end of the first photocoupler 410 and the second voltage source V2, and a resistor formed between the other end of the second photocoupler 420 and the second voltage source V2.

Here, the second voltage source V2 may provide a voltage for driving the processor 160. In addition, a photocoupler is an optoelectronic device in which a light-emitting device and a light-receiving device are optically coupled and packaged together for the purpose of transmitting an electrical signal while electrically isolating circuits from each other, and since one end and the other end of the photocoupler are electrically isolated, even when a voltage of the first voltage source V1 is changed, the driving voltage of the processor 160 is not affected and thus, the voltage of the first voltage source V1 may be freely changed.

Compared with FIG. 2, in FIG. 2, the first voltage source V1 may provide a voltage for driving the processor 160, and when the voltage is different, the processor 160 may not operate properly or may be damaged. On the other hand, when the electronic apparatus 100 further includes the photocouplers, contact may be detected using a voltage other than the voltage for driving the processor 160, thereby improving expandability.

Alternatively, as illustrated in FIG. 4, the electronic apparatus 100 may further include, in addition to the first photocoupler 410 and the second photocoupler 420, a first Schmitt trigger circuit 430 including one end connected to the other end of the first photocoupler 410, and a second Schmitt trigger circuit 440 including one end connected to the other end of the second photocoupler 420. The processor 160 may identify whether an error occurs in the electronic apparatus 100 based on the other end of the first Schmitt trigger circuit 430 and the other end of the second Schmitt trigger circuit 440. The Schmitt trigger circuit is a circuit that converts any input waveform into a square wave, such that distinction between a high value and a low value may become clearer.

Meanwhile, in FIGS. 2 and 4, whether the first conductor 120 and the second conductor 130 are in contact is illustrated by a switch. In some embodiments, the present disclosure may also be applied to a configuration in which an actual switch is used. For example, the electronic apparatus 100 may further include a switch that connects the first conductor 120 and the second conductor 130, and the processor 160 may identify whether an error occurs in the switch based on the first voltage and the second voltage.

Through the above-described structure, an input voltage may be easily changed, and the electronic apparatus may be applied to various devices.

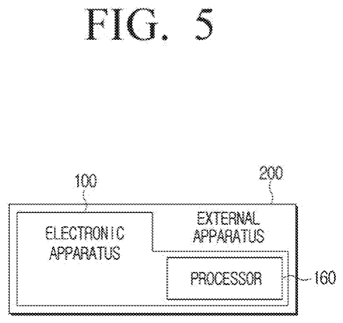

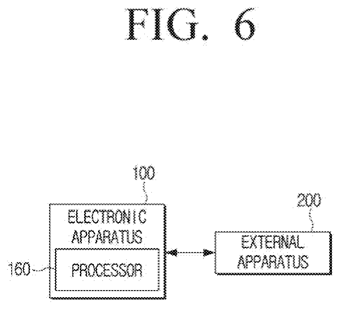

FIGS. 5 and 6 are block diagrams provided to explain a structure and utilization of an electronic apparatus according to an embodiment.

The electronic apparatus 100 may be implemented in a form that does not include the processor 160. For example, the electronic apparatus 100 may be implemented to include a transistor 110 including a drain terminal connected to the first voltage source V1, a first conductor 120 including one end connected to a gate terminal of the transistor 110, a second conductor 130 including one end connected to a source terminal of the transistor 110, a first resistor 140 connecting the first voltage source and the other end of the first conductor 120, a second resistor 150 connecting ground and the other end of the second conductor 130, and a third resistor 220 connecting the gate terminal of the transistor 110 and ground.

In this case, the electronic apparatus 100 may provide, as outputs, a voltage at the other end of the first conductor 120 and a voltage at the other end of the second conductor 130 through a GPIO 1 pin and a GPIO 2 pin, respectively.

Alternatively, the electronic apparatus 100 may further include the first photocoupler 410 including one end connected to the other end of the first conductor 120 and the other end connected to the second voltage source V2, and the second photocoupler 420 including one end connected to the other end of the second conductor 130 and the other end connected to the second voltage source V2. The electronic apparatus 100 may further include a resistor formed between the other end of the first photocoupler 410 and the second voltage source V2, and a resistor formed between the other end of the second photocoupler 420 and the second voltage source V2.

In this case, a voltage at the other end of the first photocoupler 410 may be determined based on the voltage at the other end of the first conductor 120, and a voltage at the other end of the second photocoupler 420 may be determined based on the voltage at the other end of the second conductor 130. The electronic apparatus 100 may provide, as outputs, a voltage at the other end of the first photocoupler 410 and a voltage at the other end of the second photocoupler 420 through a GPIO 1 pin and a GPIO 2 pin, respectively.

Alternatively, the electronic apparatus 100 may further include, in addition to the first photocoupler 410 and the second photocoupler 420, the first Schmitt trigger circuit 430 including one end connected to the other end of the first photocoupler 410, and the second Schmitt trigger circuit 440 including one end connected to the other end of the second photocoupler 420.

In this case, the electronic apparatus 100 may provide, as outputs, a voltage at the other end of the first Schmitt trigger circuit 430 and a voltage at the other end of the second Schmitt trigger circuit 440 through a GPIO 1 pin and a GPIO 2 pin, respectively.

As illustrated in FIG. 5, the electronic apparatus 100 may be connected to and used with an external apparatus 200. Here, although the external apparatus 200 includes the processor 160, FIG. 5 illustrates, for convenience of description, a form in which the electronic apparatus 100 includes the processor 160 as the electronic apparatus 100 is connected to the external apparatus 200.

In this case, as the electronic apparatus 100 is connected to the external apparatus 200, the GPIO 1 pin and the GPIO 2 pin may be connected to the processor 160. In addition, the electronic apparatus 100 may operate by receiving a voltage supplied from the external apparatus 200, and the processor 160 may identify whether external pressure is applied to the electronic apparatus 100 and whether an error occurs in the electronic apparatus 100 based on voltages of the GPIO 1 pin and the GPIO 2 pin.

Alternatively, as illustrated in FIG. 6, the electronic apparatus 100 may be implemented in a form that further includes the processor 160. In this case, the processor 160 is connected to the GPIO 1 pin and the GPIO 2 pin, and may identify whether external pressure is applied to the electronic apparatus 100 and whether an error occurs in the electronic apparatus 100 based on the voltages of the GPIO 1 pin and the GPIO 2 pin. The electronic apparatus 100 may further include a communication interface, and he processor 160 may control the communication interface to transmit, to the external apparatus 200, information regarding whether contact occurs or error information indicating that an error has occurred in the electronic apparatus 100.

Here, the communication interface is configured to perform communication with various types of external apparatuses according to various types of communication methods. For example, the electronic apparatus 100 may perform communication with an external apparatus through a communication interface.

The communication interface may include a Wi-Fi module, a Bluetooth module, an infrared communication module, a wireless communication module, etc. Here, each communication module may be implemented in the form of at least one hardware chip.

The Wi-Fi module and the Bluetooth module may perform communication using a Wi-Fi method and a Bluetooth method, respectively. When using a Wi-Fi module or a Bluetooth module, various connection information such as SSID and session keys are first transmitted and received, and various information can be transmitted and received after establishing communication connection using this. The infrared communication module performs communication according to an infrared Data Association (IrDA) communication technology which transmits data wirelessly over a short distance using infrared rays between optical light and millimeter waves.

The wireless communication module may include at least one communication chip that performs communication according to various wireless communication standards such as Zigbee, 3rd Generation (3G), 3rd Generation Partnership Project (3GPP), Long Term Evolution (LTE), LTE advanced (LTE-A), 4th Generation (4G), 5th Generation (5G), etc.

Alternatively, the communication interface may include a wired communication interface such as HDMI, DP, Thunderbolt, USB, RGB, D-SUB, DVI, etc.

In addition, the communication interface may include at least one wired communication module that performs communication using a Local Area Network (LAN) module, an Ethernet module, or a pair cable, a coaxial cable, an optical fiber cable, etc.

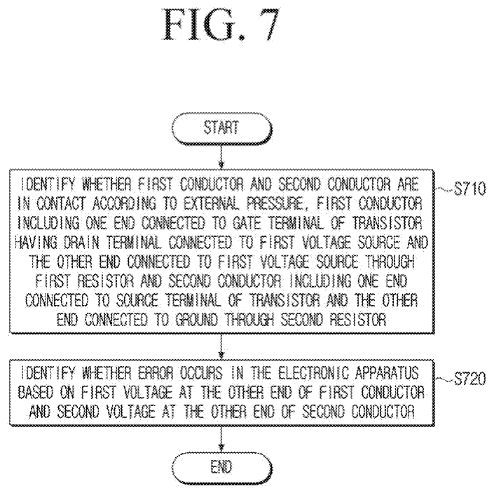

FIG. 7 is a flowchart provided to explain a method of controlling an electronic apparatus according to an embodiment.

According to external pressure, whether a first conductor and a second conductor are in contact is identified (S710), wherein the first conductor includes one end connected to a gate terminal of a transistor having a drain terminal connected to a first voltage source and another end connected to the first voltage source through a first resistor, and the second conductor includes one end connected to a source terminal of the transistor and another end connected to ground through a second resistor. Then, whether an error occurs in the electronic apparatus is identified based on a first voltage at the other end of the first conductor and a second voltage at the other end of the second conductor (S720).

In addition, in the step of identifying whether an error occurs (S720), when the first voltage and the second voltage are identical, it may be identified that no error has occurred in the electronic apparatus, and when the first voltage and the second voltage are different, it may be identified that an error has occurred in the electronic apparatus.

Further, in the step of identifying whether an error occurs (S720), when the first voltage and the second voltage are low values, it may be identified that the first conductor and the second conductor are in contact with each other; when the first voltage and the second voltage are high values, it may be identified that the first conductor and the second conductor are not in contact with each other; and when the first voltage is a high value and the second voltage is a low value, it may be identified that an error has occurred in the electronic apparatus.

In addition, the electronic apparatus may be included in an external apparatus, and the controlling method may further include controlling the external apparatus based on contact information indicating that the first conductor and the second conductor are in contact with each other or error information indicating that an error has occurred in the electronic apparatus.

Further, the first resistor may have a resistance value greater than that of the second resistor such that, when the first conductor and the second conductor are in contact with each other, the first voltage and the second voltage are identified as low values.

In addition, the electronic apparatus may further include a third resistor connecting the gate terminal of the transistor and ground.

Further, the electronic apparatus may further include a first photocoupler including one end connected to the other end of the first conductor and the other end connected to a second voltage source, and a second photocoupler including one end connected to the other end of the second conductor and the other end connected to the second voltage source, and the step of identifying whether an error occurs (S720) may include identifying whether an error occurs in the electronic apparatus based on the other end of the first photocoupler and the other end of the second photocoupler.

In addition, the first voltage source may change a voltage, and the second voltage source may provide a voltage for driving a processor included in the electronic apparatus.

Further, the electronic apparatus may further include a first Schmitt trigger circuit including one end connected to the other end of the first photocoupler and a second Schmitt trigger circuit including one end connected to the other end of the second photocoupler, and the step of identifying whether an error occurs (S720) may include identifying whether an error occurs in the electronic apparatus based on the other end of the first Schmitt trigger circuit and the other end of the second Schmitt trigger circuit.

In addition, the electronic apparatus may further include a switch connecting the first conductor and the second conductor, and the step of identifying whether an error occurs (S720) may include identifying whether an error occurs in the switch based on the first voltage and the second voltage.

As described above, according to various embodiments of the present disclosure, the electronic apparatus may detect contact information while also detecting whether an error occurs through a simple circuit configuration.

In addition, since only simple components such as a transistor are added, a manufacturing cost of the electronic apparatus may be reduced.

Further, through the above-described structure, an input voltage may be easily changed, which may be applied to various devices.

Meanwhile, the above-described various embodiments may be implemented as software including instructions stored in machine-readable storage media, which can be read by machine (e.g.: computer). The machine may be a device that invokes the stored instruction from the storage medium and can be operated based on the invoked instruction, and may include an electronic device (e.g.: electronic apparatus (A)) according to the embodiments disclosed herein. In case that the instruction is executed by the processor, the processor may directly perform a function corresponding to the instruction or other components may perform the function corresponding to the instruction under control of the processor. The instruction may include codes generated or executed by a compiler or an interpreter. The machine-readable storage media may be provided in a non-transitory storage medium. Here, ‘non-transitory storage medium’ merely means that the storage medium is tangible without including a signal, and does not distinguish whether data are semi-permanently or temporarily stored in the storage medium.

In addition, according to an embodiment, the methods according to an embodiment may be included and provided in a computer program product. The computer program product may be traded as a product between a seller and a purchaser. The computer program product may be distributed in the form of a storage medium (e.g., compact disc read only memory (CD-ROM)) that is readable by devices, or may be distributed through an application store (e.g., PlayStore™). In the case of an online distribution, at least part of the computer program product may be at least temporarily stored in a storage medium such as a server of the manufacturer, a server of an application store, or the memory of a relay server or may be temporarily generated.

Meanwhile, the above-described various embodiments may be implemented in a recording medium that can be read by a computer or a similar device using software, hardware, or a combination thereof. In some cases, embodiments described herein may be implemented by a processor itself. According to software implementation, embodiments such as procedures and functions described in this specification may be implemented as separate software. Each software may perform one or more functions and operations described in this disclosure.

Meanwhile, computer instructions for performing processing operations of the robot device according to the above-described various embodiments may be stored in a non-transitory computer-readable medium. When being executed by a processor of a specific device, the computer instructions stored in such a non-transitory computer-readable medium allows the specific device to perform processing operations in the electronic device according to the above-described various embodiments. The non-transitory computer-readable medium refers to a medium that stores data semi-permanently and can be read by a device, rather than a medium that stores data for a short period of time, such as registers, caches, memory, etc. Specific examples of the non-transitory computer-readable medium may include CD, DVD, hard disk, Blu-ray disk, USB, memory card, ROM, etc.

Further, the components (e.g., modules or programs) according to various embodiments described above may include a single entity or a plurality of entities, and some of the corresponding sub-components described above may be omitted or other sub-components may be further included in the various embodiments. Alternatively or additionally, some components (e.g., modules or programs) may be integrated into one entity and perform the same or similar functions performed by each corresponding component prior to integration. Operations performed by the modules, the programs, or the other components according to the various embodiments may be executed in a sequential manner, a parallel manner, an iterative manner, or a heuristic manner, or at least some of the operations may be performed in a different order or be omitted, or other operations may be added.

Although preferred embodiments of the present disclosure have been shown and described above, the disclosure is not limited to the specific embodiments described above, and various modifications may be made by one of ordinary skill in the art without departing from the gist of the disclosure as claimed in the claims, and such modifications are not to be understood in isolation from the technical ideas or prospect of the disclosure.

What is claimed is:

1. An electronic apparatus comprising:
a transistor comprising a drain terminal connected to a first voltage source;
a first conductor comprising a first end connected to a gate terminal of the transistor;
a second conductor comprising a first end connected to a source terminal of the transistor;
a first resistor connecting the first voltage source and a second end of the first conductor;
a second resistor connecting ground and a second end of the second conductor;
memory storing instructions; and
at least one processor configured to execute the instructions to identify whether the first conductor and the second conductor are in contact according to external pressure,
wherein the at least one processor is configured to execute the instructions to identify whether an error occurs in the electronic apparatus based on a first voltage at the second end of the first conductor and a second voltage at the second end of the second conductor.

2. The electronic apparatus of claim 1, wherein the at least one processor is configured to execute the instructions to:
based on the first voltage and the second voltage being the same, identify that no error has occurred in the electronic apparatus; or
based on the first voltage and the second voltage being different, identify that an error has occurred in the electronic apparatus.

3. The electronic apparatus of claim 2, wherein the at least one processor is configured to execute the instructions to:
based on the first voltage and the second voltage being below a first threshold, identify that the first conductor and the second conductor are in contact;
based on the first voltage and the second voltage being greater than a second threshold, identify that the first conductor and the second conductor are not in contact; or
based on the first voltage being greater than the second threshold and the second voltage being lower than the first threshold, identify that an error has occurred in the electronic apparatus.

4. The electronic apparatus of claim 3, wherein the electronic apparatus is included in an external apparatus; and
wherein the at least one processor is configured to execute the instructions to control the external apparatus based on contact information indicating that the first conductor and the second conductor are in contact or error information indicating that an error has occurred in the electronic apparatus.

5. The electronic apparatus of claim 1, wherein the first resistor has a resistance value greater than that of the second resistor such that, based on the first conductor and the second conductor being in contact, the first voltage and the second voltage are identified being below a first threshold.

6. The electronic apparatus of claim 1, further comprising:
a third resistor connecting a gate terminal of the transistor and the ground.

7. The electronic apparatus of claim 1, further comprising:
a first photo coupler comprising a first end connected to the second end of the first conductor and a second end connected to a second voltage source; and
a second photo coupler comprising a first end connected to the second end of the second conductor and a second end connected to the second voltage source,
wherein the at least one processor is configured to execute the instructions to identify whether an error occurs in the electronic apparatus based on the second end of the first photo coupler and the second end of the second photo coupler.

8. The electronic apparatus of claim 7, wherein the first voltage source is capable of changing a voltage; and
wherein the second voltage source is configured to provide a voltage for driving the at least one processor.

9. The electronic apparatus of claim 7, further comprising:
a first Schmitt trigger circuit comprising a first end connected to the second end of the first photo coupler; and
a second Schmitt trigger circuit comprising a first end connected to the second end of the second photo coupler,
wherein the at least one processor is configured to execute the instructions to identify whether an error occurs in the electronic apparatus based on the second end of the first Schmitt trigger circuit and the second end of the second Schmitt trigger circuit.

10. The electronic apparatus of claim 1, further comprising:
a switch connecting the first conductor and the second conductor,
wherein the at least one processor is configured to execute the instructions to identify whether an error occurs in the switch based on the first voltage and the second voltage.

11. A method of controlling an electronic apparatus, comprising:
identifying whether a first conductor and a second conductor are in contact according to external pressure, wherein
the first conductor comprises 1) a first end connected to a gate terminal of a transistor having a drain terminal connected to a first voltage source and 2) a second end connected to the first voltage source through a first resistor, and
the second conductor comprises a first end connected to a source terminal of the transistor and a second end connected to ground through a second resistor; and
identifying whether an error occurs in the electronic apparatus based on a first voltage at the second end of the first conductor and a second voltage at the second end of the second conductor.

12. The method of claim 11, wherein the identifying whether an error occurs comprises:
based on the first voltage and the second voltage being the same, identifying that no error has occurred in the electronic apparatus; or
based on the first voltage and the second voltage being different, identifying that an error has occurred in the electronic apparatus.

13. The method of claim 12, wherein the identifying whether an error occurs comprises:
based on the first voltage and the second voltage being below a first threshold, identifying that the first conductor and the second conductor are in contact;
based on the first voltage and the second voltage being greater than a second threshold, identifying that the first conductor and the second conductor are not in contact; or
based on the first voltage being greater than the second threshold and the second voltage being lower than the first threshold, identifying that an error has occurred in the electronic apparatus.

14. The method of claim 13, wherein the electronic apparatus is included in an external apparatus; and
wherein the method further comprises:
controlling the external apparatus based on contact information indicating that the first conductor and the second conductor are in contact or error information indicating that an error has occurred in the electronic apparatus.

15. The method of claim 11, wherein the first resistor has a resistance value greater than that of the second resistor such that, based on the first conductor and the second conductor being in contact, the first voltage and the second voltage are identified being below a first threshold.
